(19) United States
(12) Patent Application Publication
(10) Pub. No.: US 2023/0314565 A1
(43) Pub. Date: Oct. 5, 2023

(54) RADAR SIGNAL PROCESSING METHOD WITH CLUTTER SUPPRESSION CALIBRATION FUNCTION AND RADAR SENSOR APPLYING THE SAME

(71) Applicant: Korea Electronics Technology Institute, Seongnam-si (KR)

(72) Inventors: Sung Ho LEE, Seoul (KR); Kang Il CHO, Seongnam-si (KR); Yong Chul JUNG, Seoul (KR)

(73) Assignee: Korea Electronics Technology Institute, Seongnam-si (KR)

(21) Appl. No.: 17/940,054

(22) Filed: Sep. 8, 2022

(30) Foreign Application Priority Data
Apr. 1, 2022 (KR) 10-2022-0040856

(51) Int. Cl. G01S 7/40; G01S 13/34

(52) U.S. Cl. CPC G01S 7/4056; G01S 13/34

(57) ABSTRACT

There are provided a radar signal processing method with a clutter suppression calibration function, and a radar sensor applying the same. A radar sensor according to an embodiment of the disclosure includes: a transmitter configured to transmit a radar signal; a receiver configured to receive a reflected radar signal; a mixer configured to down-convert the radar signal received through the receiver into an IF signal; a memory configured to store clutter information; a restoring unit configured to restore a clutter signal from the clutter information stored in the memory; and a calculator configured to remove a clutter signal from the IF signal down-converted at the mixer, by using the clutter signal restored at the restoring unit. Accordingly, it is easy to detect a radar target by removing objects other than a target easily in various indoor environments, and an SNR and a dynamic range may increase.

### CROSS-REFERENCE TO RELATED APPLICATION(S) AND CLAIM OF PRIORITY

This application is based on and claims priority under 35 U.S.C. § 119 to Korean Patent Application No. 10-2022-0040856, filed on Apr. 1, 2022, in the Korean Intellectual Property Office, the disclosure of which is herein incorporated by reference in its entirety.

### BACKGROUND

### Field

The disclosure relates to radar signal processing technology, and more particularly, to a radar signal processing method which is capable of enhancing a wide dynamic range and a signal-to-noise ratio (SNR), by enhancing a structure which worsens a dynamic range of a signal due to a clutter environment provided when a frequency modulated continuous wave (FMCW) radar sensor is used indoors, and a radar sensor applying the same.

### Description of Related Art

Recently, there is an attempt to seek a method for utilizing radar sensors, which have been used for a military purpose, variously for home appliances and IoT sensors. However, in an indoor environment, it may be difficult to detect only a desired target due to radio waves reflected from a close object, a wall, or an obstacle due to characteristics of the radio waves, and many reflected waves may be received from undesired objects.

Since radio waves reflected from various obstacles are received along with radio waves from a desired object, an amplification factor of an amplifier at a reception end may not greatly increase and there may be a difficulty in achieving a desirable SNR to process signals.

In particular, when there exists an obstacle closer than a target, a clutter (obstacle) signal which is stronger than a desired target signal may exist, and it may be difficult to detect the desired target signal. In this case, when great amplification is performed, saturation may occur in an analogue circuit such as an analogue-to-digital converter (ADC), and it may be difficult to perform a normal operation.

This problem may become more serious when there exist various objects such as a wall, furniture, things around an indoor environment where a radar sensor is utilized, and enhancement of performance of the radar sensor which is used indoors for the purpose of detecting occupancy or a vital sign may be suppressed.

### SUMMARY

The disclosure has been developed to address the above-discussed deficiencies of the prior art, and an object of the present disclosure is to provide a radar signal processing method which overcomes limitations of simple amplification and filtering, which are widely used for related-art FMCW radar target detection, and is capable of amplifying a size of a desired signal and using a wide dynamic range by pre-measuring clutter information reflected from an undesired obstacle and removing the clutter, and is capable of expanding a target distance and enhancing an SNR, and a radar sensor applying the same.

According to an embodiment of the disclosure to achieve the above-described object, a radar sensor may include: a transmitter configured to transmit a radar signal; a receiver configured to receive a reflected radar signal; a mixer configured to down-convert the radar signal received through the receiver into an intermediate frequency (IF) signal; a memory configured to store clutter information; a restoring unit configured to restore a clutter signal from the clutter information stored in the memory; and a calculator configured to remove a clutter signal from the IF signal down-converted at the mixer, by using the clutter signal restored at the restoring unit.

The clutter information may be information regarding a radar signal that is reflected from an object which is not a target in an indoor environment. The clutter signal restored at the restoring unit may be a signal of an IF band. The clutter information may be an average of pieces of clutter information generated multiple times. The clutter information may be generated and stored in the memory in a store section. The clutter information may be periodically or aperiodically updated.

According to an embodiment, the radar sensor may further include: an analog-to-digital converter (ADC) configured to convert the IF signal outputted from the calculator into a digital signal; and a signal processor configured to detect target information from the digital signal converted at the ADC.

The clutter information may be generated by down-converting a radar signal, which is received through the receiver in an indoor environment without a target, into an IF signal through the mixer, and then converting the IF signal into a digital signal through the ADC.

The restoring unit may include a digital-to-analog converter (DAC) configured to convert the clutter information stored in the memory into an analogue signal. The restoring unit may further include: a filter configured to filter the analogue signal converted at the DAC; and a gain control amplifier (GCA) configured to adjust a gain of the analogue signal outputted from the filter.

The transmitter may adjust a gain of the radar signal and then may amplify power and may transmit the radar signal. The mixer may generate the IF signal by mixing the radar signal received through the receiver and the radar signal inputted to the transmitter.

According to an embodiment of the disclosure, the radar sensor may further include a filter configured to filter the IF signal outputted from the mixer and to output the IF signal to the calculator.

According to an embodiment of the disclosure, the radar sensor may further include a controller configured to control a timing to output the clutter information stored in the memory, based on a timing of the radar signal outputted from the receiver.

According to another embodiment of the disclosure, a radar signal processing method may include: transmitting a radar signal; receiving a reflected radar signal; down-converting the radar signal received through a receiver into an intermediate frequency (IF) signal; restoring a clutter signal from clutter information stored in a memory; and removing a clutter signal from the IF signal down-converted at a mixer, by using the clutter signal restored at a restoring unit.

According to another embodiment of the disclosure, a radar sensor may include: a mixer configured to down-convert a radar signal into an intermediate frequency (IF) signal; a memory configured to store clutter information; a restoring unit configured to restore a clutter signal from the clutter information stored in the memory; and a calculator configured to remove a clutter signal from the IF signal down-converted at the mixer, by using the clutter signal restored at the restoring unit.

According to another embodiment of the disclosure, a radar signal processing method may include: down-converting a radar signal into an IF signal; restoring a clutter signal from clutter information stored in a memory; and removing a clutter signal from the IF signal down-converted at a mixer, by using the clutter signal restored at a restoring unit.

According to another embodiment of the disclosure, a radar signal processing method may include: generating and storing clutter information; down-converting a radar signal into an IF signal; restoring a clutter signal from the stored clutter information; and removing a clutter signal from the IF signal down-converted at a mixer, by using the clutter signal restored at a restoring unit.

According to embodiments of the disclosure as described above, clutter information of an indoor environment may be pre-generated/stored, and may be utilized to remove a clutter from a radar signal when a target is detected, so that a dynamic range may increase.

In addition, according to embodiments of the disclosure, it is easy to detect a radar target by removing objects other than a target easily in various indoor environments, and clutter information may be generated/stored when necessary, so that the radar sensor may be utilized for various purposes.

Other aspects, advantages, and salient features of the invention will become apparent to those skilled in the art from the following detailed description, which, taken in conjunction with the annexed drawings, discloses exemplary embodiments of the invention.

Before undertaking the DETAILED DESCRIPTION OF THE INVENTION below, it may be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like. Definitions for certain words and phrases are provided throughout this patent document, those of ordinary skill in the art should understand that in many, if not most instances, such definitions apply to prior, as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 is a view illustrating a structure of an FMCW radar sensor to which the disclosure is applicable;

FIG. 2 is a view illustrating a signal processing method of the FMCW radar sensor shown in FIG. 1;

FIG. 3 is a view illustrating a structure of an FMCW radar sensor according to an embodiment of the disclosure;

FIG. 4 is a view illustrating a clutter information generation/storage method;

FIG. 5 is a view illustrating a signal processing method of the FMCW radar sensor shown in FIG. 3;

FIG. 6 is a view illustrating a structure of an FMCW radar sensor according to another embodiment of the disclosure; and

FIG. 7 is a flowchart provided to explain an FMCW radar signal processing method according to still another embodiment of the disclosure.

### DETAILED DESCRIPTION

Hereinafter, the disclosure will be described in detail with reference to the accompanying drawings.

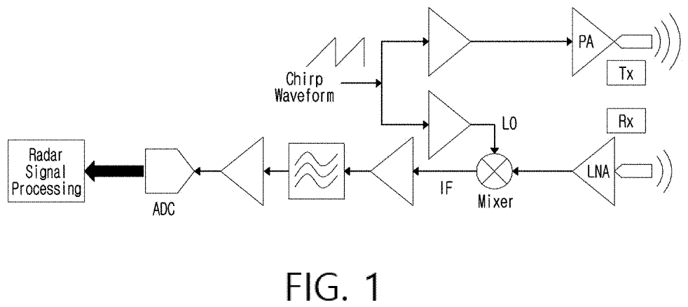

FIG. 1 is a view illustrating a structure of an FMCW radar sensor to which the disclosure is applicable. The FMCW radar sensor may output electromagnetic waves through a transmitter while modulating a frequency, specifically, linearly increasing a frequency of electromagnetic waves, and may receive electromagnetic waves reflected from a target through a receiver.

A radio frequency (RF) which is received in this way may be down-converted into an intermediate frequency (IF) signal along with a transmitted RF frequency through a mixer. As a distance to a target increases from the radar sensor, a frequency difference between the received RF frequency and the transmitted RF frequency may increase, and therefore, the IF signal may have a high-frequency component. That is, in the FMCW radar sensor, the distance to the target and the frequency of the IF signal have a proportional relationship.

A target or an obstacle which is close to the sensor may have an IF signal of a low frequency, and may have a great magnitude according to a size of an object. To the contrary, a target or an obstacle which is far away from the sensor may have an increasing IF frequency and may have a magnitude determined according to a size of an object.

A speed of a target may be measured through a Doppler component in the FMCW radar sensor. In the case of a target which moves far away from the radar sensor, a frequency may be reduced due to the Doppler effect. Such a change in the frequency caused by the Doppler effect is so small that the change appears as a change in an IF signal phase size. In the case of a target which moves far away from the sensor, the frequency may be reduced and the phase may be rotated to the right on polar coordinates. The speed of the target may be measured by using such a phase change.

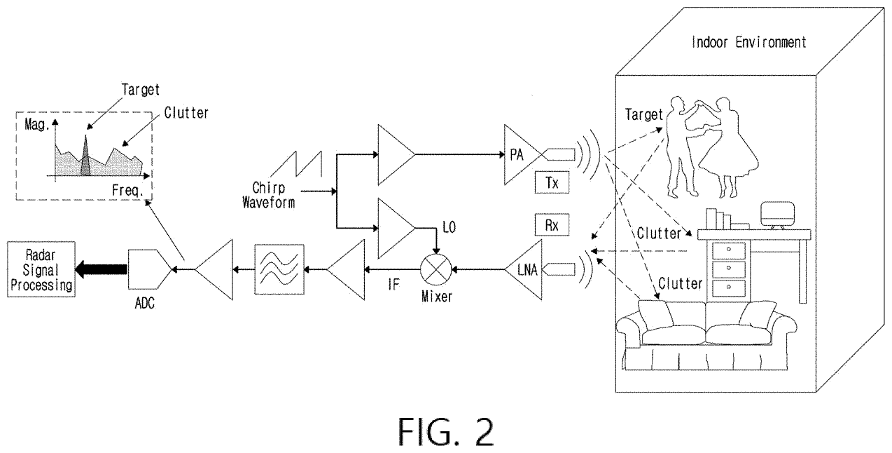

However, a problem may arise when the FMCW radar sensor shown in FIG. 1 is utilized indoors. Since there may exist a wall, furniture, and objects around the sensor as shown in FIG. 2, signals reflected from various clutters (objects other than a target, an environment, etc.) are also received, and accordingly, worsen a dynamic range and an SNR at a reception end, eventually suppressing enhancement of performance of the radar sensor for detecting occupancy or a vital sign indoors.

An embodiment of the disclosure proposes an FMCW radar signal processing method provided with a clutter suppression calibration function, and an FMCW radar sensor applying the same.

The FMCW radar sensor according to an embodiment may store a clutter signal in an indoor environment in an internal memory as digital information, and may have a closed loop circuit which is added to an analogue end to restore a clutter signal of an IF band from the stored clutter information, and may use the closed loop circuit to remove a clutter signal from a received signal.

Unlike a radar signal reflected from a moving target, a clutter signal from an obstacle, a background, an environment which is fixed is always constant, and therefore, clutter information may be acquired and stored in the internal memory in a store process.

In addition, the clutter information stored in the internal memory may be restored as a clutter signal of an IF band, and may be used to calibrate a received signal at an analogue end, such that a clutter signal is removed from a signal inputted to an ADC, and an SNR is enhanced. Accordingly, the ADC may be allowed to detect a great target signal, and a dynamic range may increase.

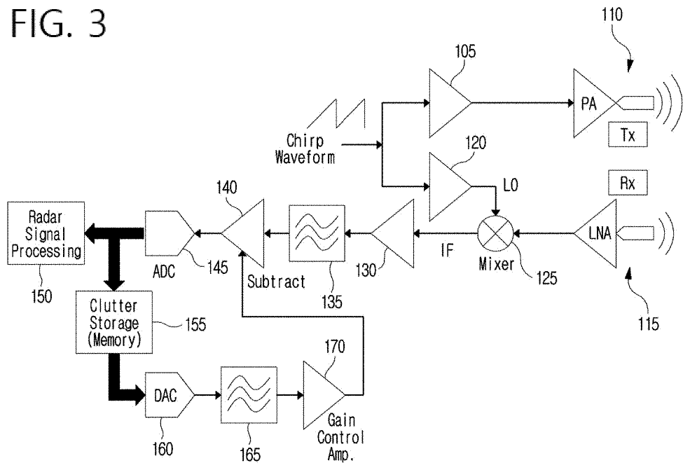

FIG. 3 is a view illustrating a structure of an FMCW radar sensor according to an embodiment of the disclosure. As shown in the drawing, the FMCW radar sensor according to an embodiment may include a gain control amplifier (GCA)-1 105, a transmitter 110, a receiver 115, a GCA-2 120, a mixer 125, a GCA-3 130, an analogue filter-1 135, a calculator 140, an analog-to-digital converter (ADC) 145, a digital signal processor 150, a clutter memory 155, a digital-to-analog converter (DAC) 160, an analogue filter-2 165, and a GCA-4 170.

The GCA-1 105 may adjust a gain of a chirp signal to utilize as a radar signal, and the transmitter 110 may amplify power of the chirp signal and transmit the chirp signal, and the receiver 115 may receive radar signals reflected from a target and a clutter.

The GCA-2 120 may adjust the gain of the chirp signal which is utilized as a radar signal at the transmitter 110, and may apply the chirp signal to the mixer 125. The mixer 125 may mix the radar signal received at the receiver 115 and the radar signal applied from the GCA-2 120, and may down-convert the signal into an IF signal.

The GCA-3 130 may adjust a gain of the IF signal outputted from the mixer 125, and the analogue filter-1 135 may filter the IF signal the gain of which is adjusted at the GCA-3 130, and may output the filtered signal to the calculator 140.

The calculator 140 may subtract a clutter signal from the IF signal outputted from the analogue filter-1 135, and may leave only a target signal in the radar signal. The clutter signal may be a signal that is recovered from clutter information stored in the clutter memory 155, which will be described below. The clutter information and a method of restoring a clutter signal therefrom will be described in detail.

The ADC 145 may convert the IF signal from which the clutter signal is removed, outputted from the calculator 140, into a digital signal, and the digital signal processor 150 may process the digital signal outputted from the ADC 145 and may detect information regarding the target (distance, speed, size, etc.).

The clutter memory 155 may be an internal storage in which clutter information regarding an indoor environment is stored. The clutter information may be generated by down-converting a radar signal, which is transmitted from the transmitter 110 and received at the receiver 115 in an indoor environment without a target, into an IF signal through the mixer 125, and then converting the IF signal into a digital signal through the ADC 145.

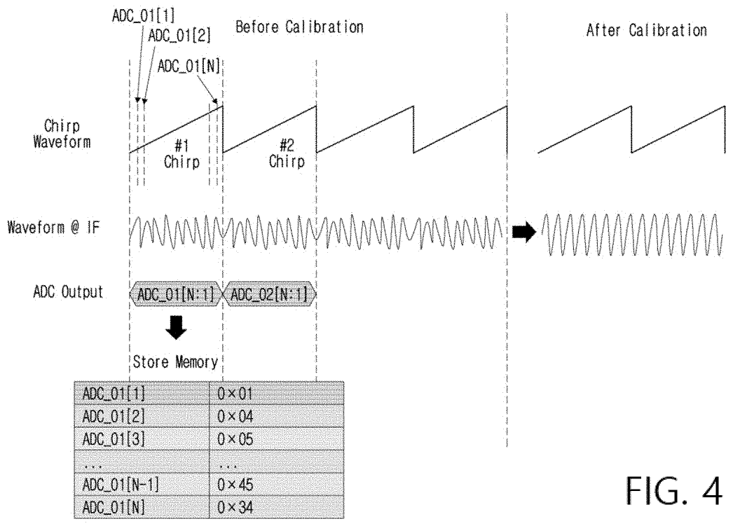

FIG. 4 is a view illustrating a method of generating/storing clutter information. As shown in the drawing, clutter information may be generated/stored in a store section. In order to generate clutter information, an indoor environment without a target should be established in the store section.

As shown in the upper portion of FIG. 4, a plurality of pieces of clutter information may be generated multiple times through a plurality of chirp signals Chirp #1, Chirp #2, . . . , and an average of the generated clutter information may be utilized as final clutter information.

The number of times clutter information is generated is not limited, and clutter information may be generated one time.

Furthermore, a time to generate clutter information is not limited. The clutter information may be implemented to be updated periodically, or may be implemented to be updated by operating an aperiodic store mode. The store mode may be performed when it is determined that target detection accuracy is degraded.

A similar radio wave is received for every chirp signal when the chirp signal the frequency of which is modulated is iteratively operated, as shown in the lower portion of FIG. 4. Accordingly, when clutter information is stored in the clutter memory 155, data that is converted into digital data through the ADC 145 through a minority of chirp signals in an initial environment without a target may be stored in the clutter memory 155 as many as the number of samples.

For example, when 128 samples are sampled in one chirp signal and are converted into digital data by the ADC 145, the ADC 145 of 12 bits has only to have a memory of 128×12b=1536 bits in order to store clutter information regarding one chirp signal.

Reference is made back to FIG. 3. The clutter information stored in the clutter memory 155 as a digital signal may be restored as a clutter signal of an IF band by the DAC 160, the analogue filter-2 165, and the GCA-4 170.

Specifically, the DAC 160 may convert the clutter information stored in the clutter memory 155 into an analogue signal, and the analogue filter-2 165 may filter the analogue signal converted by the DAC 160, and the GCA-4 170 may adjust a gain of the analogue signal outputted from the analogue filter-2 165 and may restore a clutter signal of an IF band.

In order to remove a switching noise and to adjust a size by the DAC 160, filtering by the analogue filter-2 165 and reducing the gain by the GCA-4 170 may be required.

The clutter signal restored through the above-described process may be applied to the calculator 140, and may be utilized to remove a clutter signal from an IF signal which includes a target signal and a clutter signal, and to extract only the target signal.

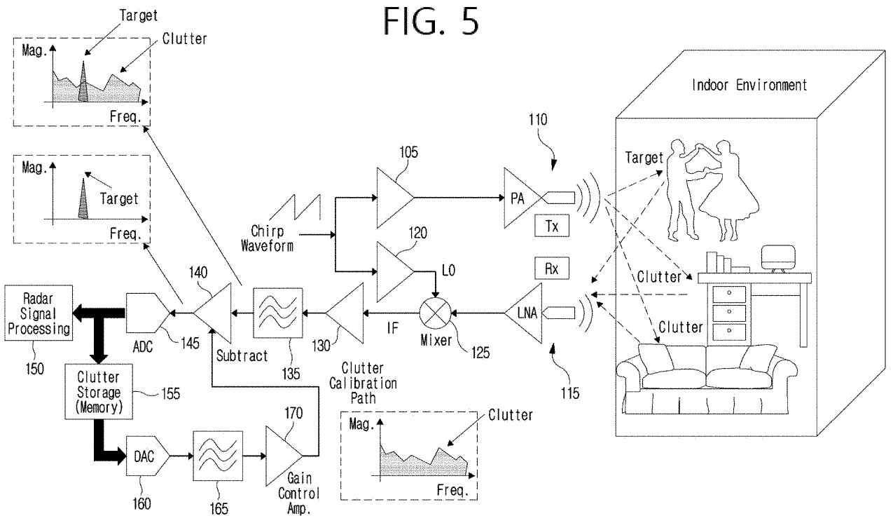

According to an embodiment of the disclosure as described above, the FMCW radar sensor may digitize a clutter signal and store the same in the clutter memory 155 as clutter information, and may restore a clutter signal from the stored clutter information and feed the same back to an analogue end to allow a clutter signal to be removed. This process is illustrated in FIG. 5.

When a clutter signal is removed, only a target signal is left. Accordingly, a high gain may be set at the GCA-3 130, and also, the ADC 145 may convert a more amplified target signal into digital data, so that a wide dynamic range is guaranteed.

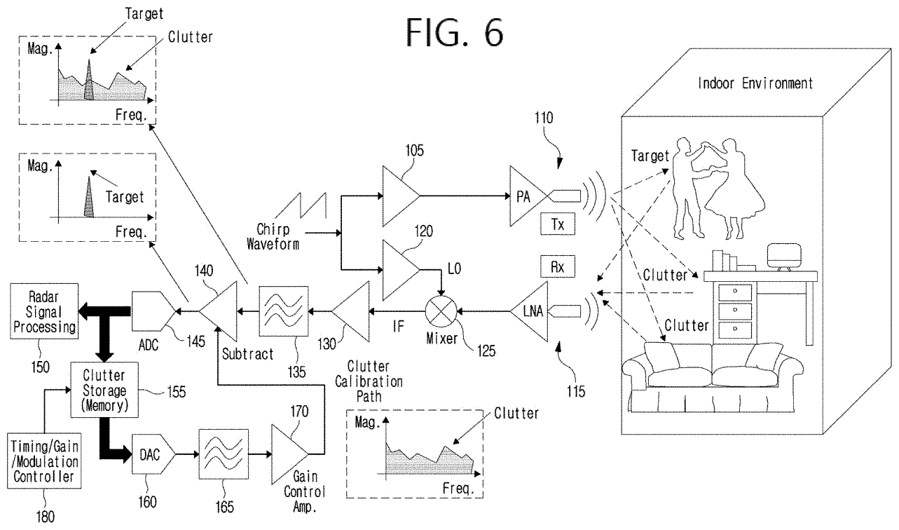

FIG. 6 is a view illustrating a structure of an FMCW radar sensor according to another embodiment of the disclosure. The FMCW radar sensor according to an embodiment is a structure that adds a controller 180 to the configuration of the FMCW radar sensor shown in FIG. 3.

The controller 180 is configured to control the clutter memory 155 or to modify/convert clutter information stored in the clutter memory 155.

Specifically, the controller 180 may control a timing to output clutter information stored in the clutter memory 155 to the DAC 160. Controlling the timing is to synchronize a radar signal and a clutter signal which are applied to the calculator 140, and to achieve this, the controller 180 may refer to timing information of the radar signal which is received through the receiver 115.

In addition, the controller 180 may adjust a size of the clutter information stored in the clutter memory 155. Adjusting the size is to match a size of a clutter signal to be applied to the calculator 140 with a size of a clutter signal included in the radar signal, and to achieve this, the controller 180 may refer to a size of the radar signal received through the receiver 115.

Furthermore, the controller 180 may modulate the clutter information by adding a modulation signal to the clutter information stored in the clutter memory 155. In other words, radar information regarding a target that is not desired to be detected, or an interference signal between the transmitter 110 and the receiver 115 may be added.

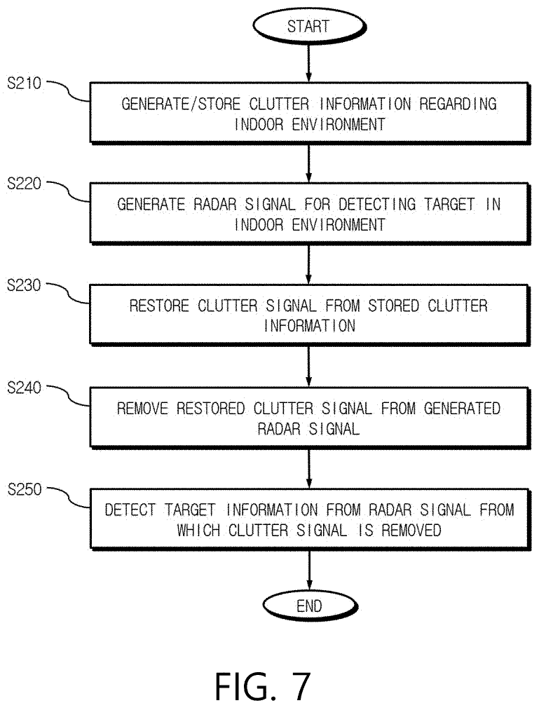

FIG. 7 is a flowchart provided to explain an FMCW radar signal processing method according to another embodiment of the disclosure.

First, clutter information regarding an indoor environment may be generated and stored in the clutter memory 155 (S210). The clutter information may be generated by down-converting a radar signal, which is transmitted from the transmitter 110 and is received at the receiver 115 in an indoor environment without a target, into an IF signal through the mixer 125, and then converting the IF signal into a digital signal through the ADC 145.

Generating the clutter information at step S210 may be performed when the FMCW radar sensor is initially operated, and may be performed periodically/aperiodically thereafter.

Next, a radar signal for detecting a target in the indoor environment may be generated (S220). The radar signal generated at step S220 is a signal resulting from down-conversion of a radar signal transmitted from the transmitter 110 and received at the receiver 115 in the indoor environment with the target into a IF signal through the mixer 125.

A clutter signal may be restored from the clutter information stored at step S210 while step S220 is performed (S230). The clutter signal may be restored through processes of converting the clutter information stored in the clutter memory 155 into an analogue signal by the DAC 160, filtering the analogue signal converted at the DAC 160 by the analogue filter-2 165, and adjusting a gain of the analogue signal outputted from the analogue filter-2 165 by the GCA-4 170.

In the process of restoring the clutter signal at step 230, the controller 180 may adjust a timing of the clutter information, may correct a magnitude, and may modulate.

Thereafter, the calculator 140 may leave only a target signal in the radar signal by removing the clutter signal restored at step S230 from the radar signal generated at step S220 (S240).

Next, the ADC 145 may convert the radar signal from which the clutter signal is removed at step S240 into a digital signal, and the digital signal processor 150 may process the digital signal and may detect information regarding the target (distance, speed, size, etc.) (S250).

Up to now, the radar signal processing method provided with the clutter suppression calibration function, and the radar sensor applying the same have been described in detail.

In the above-described embodiments, there has been proposed a structure which overcomes limitations of simple amplification and filtering, which are widely used for related-art FMCW radar target detection, and is capable of amplifying a size of a desired signal and using a wide dynamic range by pre-measuring clutter information reflected from an undesired obstacle and removing the clutter information, and is capable of expanding a target distance and enhancing an SNR.

Through embodiments of the disclosure, a dynamic range may be increased by pre-measuring clutter information and removing the same, and it may be easy to detect a radar target by removing objects other than the target easily in various indoor environments, and an environment value may be stored in a memory for initial calibration and may be used without having to refine a gain or filtering according to a measured environment.

The technical concept of the disclosure may be applied to a computer-readable recording medium which records a computer program for performing the functions of the apparatus and the method according to the present embodiments. In addition, the technical idea according to various embodiments of the present disclosure may be implemented in the form of a computer readable code recorded on the computer-readable recording medium. The computer-readable recording medium may be any data storage device that can be read by a computer and can store data. For example, the computer-readable recording medium may be a read only memory (ROM), a random access memory (RAM), a CD-ROM, a magnetic tape, a floppy disk, an optical disk, a hard disk drive, or the like. A computer readable code or program that is stored in the computer readable recording medium may be transmitted via a network connected between computers.

In addition, while preferred embodiments of the present disclosure have been illustrated and described, the present disclosure is not limited to the above-described specific embodiments. Various changes can be made by a person skilled in the art without departing from the scope of the present disclosure claimed in claims, and also, changed embodiments should not be understood as being separate from the technical idea or prospect of the present disclosure.

What is claimed is:

1. A radar sensor comprising:
a transmitter configured to transmit a radar signal;
a receiver configured to receive a reflected radar signal;
a mixer configured to down-convert the radar signal received through the receiver into an intermediate frequency (IF) signal;
a memory configured to store clutter information;
a restoring unit configured to restore a clutter signal from the clutter information stored in the memory; and
a calculator configured to remove a clutter signal from the IF signal down-converted at the mixer, by using the clutter signal restored at the restoring unit.

2. The radar sensor of claim 1, wherein the clutter information is information regarding a radar signal that is reflected from an object which is not a target in an indoor environment.

3. The radar sensor of claim 2, wherein the clutter signal restored at the restoring unit is a signal of an IF band.

4. The radar sensor of claim 2, wherein the clutter information is an average of pieces of clutter information generated multiple times.

5. The radar sensor of claim 2, wherein the clutter information is generated and stored in the memory in a store section.

6. The radar sensor of claim 2, wherein the clutter information is periodically or aperiodically updated.

7. The radar sensor of claim 1, further comprising:
an analog-to-digital converter (ADC) configured to convert the IF signal outputted from the calculator into a digital signal; and
a signal processor configured to detect target information from the digital signal converted at the ADC.

8. The radar sensor of claim 7, wherein the clutter information is generated by down-converting a radar signal, which is received through the receiver in an indoor environment without a target, into an IF signal through the mixer, and then converting the IF signal into a digital signal through the ADC.

9. The radar sensor of claim 8, wherein the restoring unit comprises a digital-to-analog converter (DAC) configured to convert the clutter information stored in the memory into an analogue signal.

10. The radar sensor of claim 9, wherein the restoring unit further comprises:
a filter configured to filter the analogue signal converted at the DAC; and
a gain control amplifier (GCA) configured to adjust a gain of the analogue signal outputted from the filter.

11. The radar sensor of claim 1, wherein the transmitter is configured to adjust a gain of the radar signal and then to amplify power and to transmit the radar signal.

12. The radar sensor of claim 1, wherein the mixer is configured to generate the IF signal by mixing the radar signal received through the receiver and the radar signal inputted to the transmitter.

13. The radar sensor of claim 1, further comprising a filter configured to filter the IF signal outputted from the mixer and to output the IF signal to the calculator.

14. The radar sensor of claim 1, further comprising a controller configured to control a timing to output the clutter information stored in the memory, based on a timing of the radar signal outputted from the receiver.

15. A radar signal processing method comprising:
transmitting a radar signal;
receiving a reflected radar signal;
down-converting the radar signal received through a receiver into an intermediate frequency (IF) signal;
restoring a clutter signal from clutter information stored in a memory; and
removing a clutter signal from the IF signal down-converted at a mixer, by using the clutter signal restored at a restoring unit.

16. A radar sensor comprising:
a mixer configured to down-convert a radar signal into an intermediate frequency (IF) signal;
a memory configured to store clutter information;
a restoring unit configured to restore a clutter signal from the clutter information stored in the memory; and
a calculator configured to remove a clutter signal from the IF signal down-converted at the mixer, by using the clutter signal restored at the restoring unit.
